(19) United States
(12) Patent Application Publication
(10) Pub. No.: US 2015/0076579 A1
(43) Pub. Date: Mar. 19, 2015

(54) SEMICONDUCTOR MEMORY DEVICE

(71) Applicant: KABUSHIKI KAISHA TOSHIBA, Tokyo (JP)

(72) Inventors: Masaki TSUJI, Mie-ken (JP); Yoshiaki FUKUZUMI, Mie-ken (JP); Haruka SAKUMA, Kanagawa-ken (JP)

(73) Assignee: KABUSHIKI KAISHA TOSHIBA, Tokyo (JP)

(21) Appl. No.: 14/194,780

(22) Filed: Mar. 2, 2014

(30) Foreign Application Priority Data
Sep. 13, 2013 (JP) 2013-191133

(51) Int. Cl. H01L 27/115

(52) U.S. Cl. CPC H01L 27/11551; H01L 27/11578
USPC 257/314

(57) ABSTRACT

According to one embodiment, in a semiconductor memory device, a block selection transistor is provided between a stacked body and a word line in a hierarchy selection area. The block selection transistor includes a plurality of semiconductor bodies, a plurality of gate insulating films, and a gate electrode. The plurality of semiconductor bodies respectively extend from the end portions of the respective electrode layers to the respective word lines. The plurality of gate insulating films are provided on the side walls of the respective semiconductor bodies. The gate electrode faces the side wall of the semiconductor body through the gate insulating film.

### CROSS-REFERENCE TO RELATED APPLICATION

This application is based upon and claims the benefit of priority from Japanese Patent Application No. 2013-191133, filed Sep. 13, 2013, the entire contents of which are incorporated herein by reference.

### FIELD

Embodiments described herein relate to a semiconductor memory device.

### BACKGROUND

There exists a memory device having a three dimensional structure in which a memory hole is formed in a stacked body with a plurality of electrode layers. The plurality of electrode layers operate as a control gate in a memory cell and a plurality of insulating layers are alternately stacked with the plurality of electrode layers. The device also includes a silicon body that becomes a channel that is formed in the side wall of the memory hole through a charge storage film.

In such a three dimensional memory device, a data erasing operation is carried out in block units of a plurality of memory cells. In this case, as the memory cell block size gets larger with an increase in the number of stacked electrode layers, the number of the memory cells (non-select cells) experiencing a voltage stress at an erasing time is increased accordingly, and a possibility of causing adjacent memory cells to change their setting is increased.

### DESCRIPTION OF THE DRAWINGS

FIG. 1 is a schematic plan view of a semiconductor memory device according to an embodiment.

FIG. 2 is a schematic perspective view of a memory cell array in the semiconductor memory device according to the embodiment.

FIG. 3 is a schematic cross sectional view of the memory cell array in the semiconductor memory device according to the embodiment.

FIG. 4 is an enlarged schematic cross sectional view of the memory cell in the semiconductor memory device according to the embodiment.

FIGS. 5A and 5B are schematic views showing a hierarchy selecting unit and a block selection transistor in the semiconductor memory device according to the embodiment.

FIGS. 6A and 6B are schematic views showing a method of forming the hierarchy selecting unit and the block selection transistor in the semiconductor memory device according to the embodiment.

FIG. 7 is a schematic view showing the method of forming the hierarchy selecting unit and the block selection transistor in the semiconductor memory device according to the embodiment.

FIG. 8 is a schematic view showing the method of forming the hierarchy selecting unit and the block selection transistor in the semiconductor memory device according to the embodiment.

FIGS. 9A and 9B are schematic views showing the method of forming the hierarchy selecting unit and the block selection transistor in the semiconductor memory device according to the embodiment.

FIGS. 10A and 10B are schematic views showing the method of forming the hierarchy selecting unit and the block selection transistor in the semiconductor memory device according to the embodiment.

FIGS. 11A and 11B are schematic views showing the method of forming the hierarchy selecting unit and the block selection transistor in the semiconductor memory device according to the embodiment.

FIGS. 12A and 12B are schematic views showing the method of forming the hierarchy selecting unit and the block selection transistor in the semiconductor memory device according to the embodiment.

FIGS. 13A and 13B are schematic views showing the method of forming the hierarchy selecting unit and the block selection transistor in the semiconductor memory device according to the embodiment.

FIGS. 14A and 14B are schematic views showing the method of forming the hierarchy selecting unit and the block selection transistor in the semiconductor memory device according to the embodiment.

FIGS. 15A and 15B are schematic views showing the method of forming the hierarchy selecting unit and the block selection transistor in the semiconductor memory device according to the embodiment.

FIGS. 16A and 16B are schematic views showing the method of forming the hierarchy selecting unit and the block selection transistor in the semiconductor memory device according to the embodiment.

FIGS. 17A and 17B are schematic views showing the method of forming the hierarchy selecting unit and the block selection transistor in the semiconductor memory device according to the embodiment.

FIG. 18 is a schematic view showing the method of forming the hierarchy selecting unit and the block selection transistor in the semiconductor memory device according to the embodiment.

FIG. 19 is a schematic view showing the method of forming the hierarchy selecting unit and the block selection transistor in the semiconductor memory device according to the embodiment.

FIG. 20 is a schematic cross sectional view of a hierarchy selecting unit and a block selection transistor in a semiconductor memory device of another embodiment.

FIG. 21 is a schematic cross sectional view showing a method of forming the hierarchy selecting unit and the block selection transistor of FIG. 20.

FIG. 22 is a schematic cross sectional view of a cylindrical semiconductor body of the block selection transistor in the semiconductor memory device in the embodiment.

### DETAILED DESCRIPTION

According to an embodiment, there is provided a semiconductor memory device capable of improving the reliability of a memory cell.

In general, according to one embodiment, a semiconductor memory device includes a substrate, a stacked body, a channel body, a memory film, a plurality of word lines, and a block selection transistor. The stacked body includes plural sublayer-electrode layers and plural sublayer-insulating layers alternately stacked one over the other on the substrate. The stacked body includes a memory cell array area and a hierarchy selection area (logic and control area) provided outside the memory cell array area. The channel body extends inside the stacked body in the stacking direction of the stacked body in the memory cell array area. The memory film is provided between the electrode layer and the channel body. The plural word lines are provided on the stacked body in the hierarchy selection area. The block selection transistor is provided between the stacked body and the word line in the hierarchy selection area. Each of the electrode layers includes an end portion extending toward the block selection transistor in the hierarchy selection area. The block selection transistor includes a plurality of semiconductor bodies, a plurality of gate insulating films, and gate electrodes. The plural semiconductor bodies respectively extend from the end portions of the respective electrode layers to the respective word lines. The plural gate insulating films are provided on the side walls of the respective semiconductor bodies. The gate electrodes respectively face the side walls of the semiconductor bodies through the gate insulating films.

Hereinafter, embodiments will be described with reference to the drawings. In the drawings, the same reference numerals are used for the same elements.

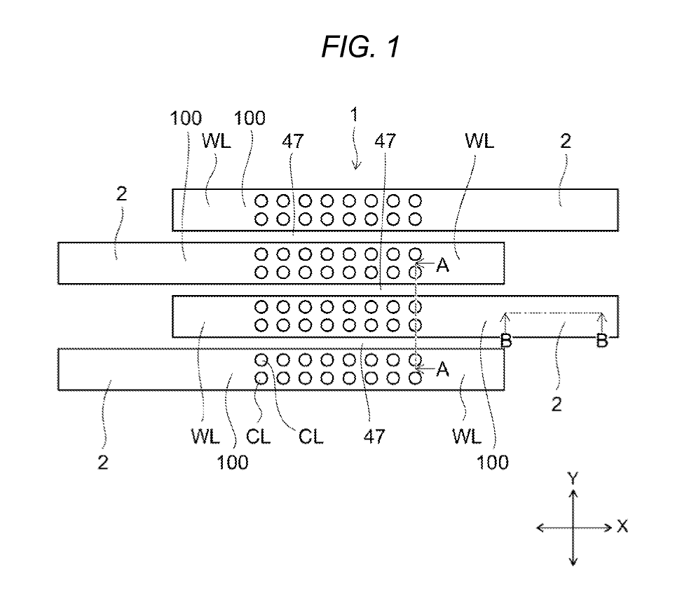

FIG. 1 is a schematic plan view of the semiconductor memory device according to the embodiment.

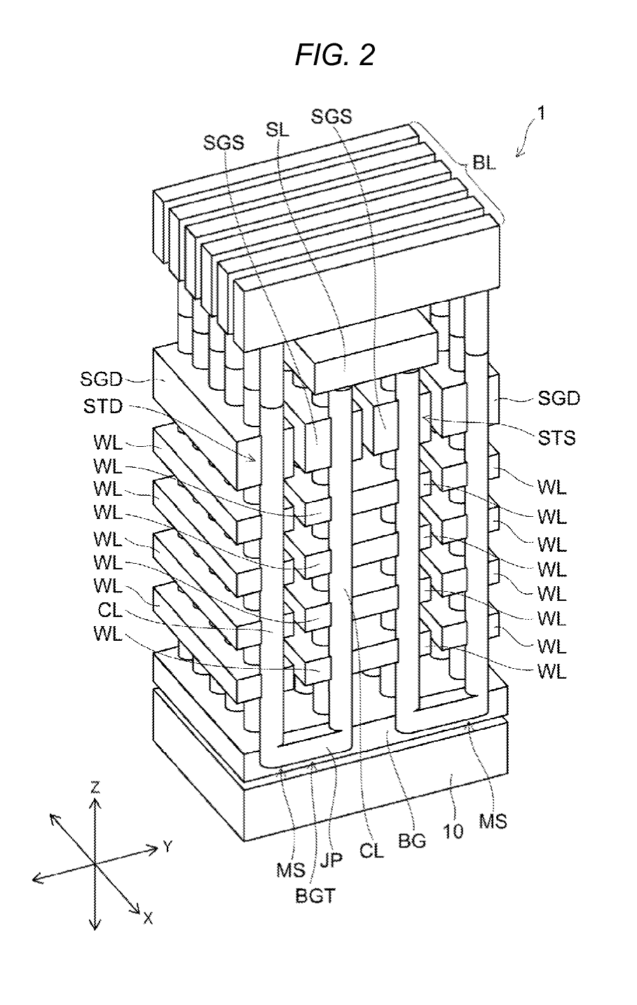

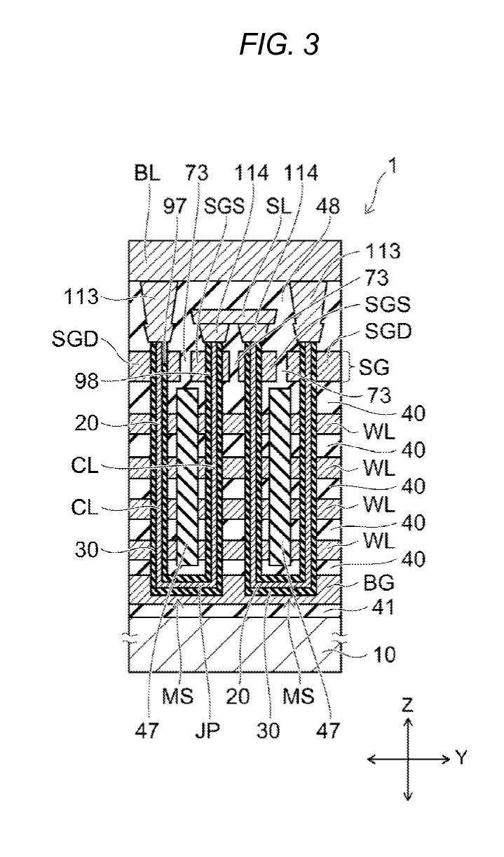

The semiconductor memory device according to the embodiment includes a memory cell array 1 and a hierarchy selecting unit 2. The memory cell array 1 and the hierarchy selecting unit 2 are provided on a substrate 10 shown in FIGS. 2 and 3. The substrate 10 is, for example, a silicon substrate.

FIG. 2 is a schematic perspective view of the memory cell array 1. In FIG. 2, insulation portions of the memory cell array 1 are not illustrated for the sake of clarity of the description of elements in FIG. 2.

In FIG. 2, two directions, mutually crossing at a right angle in a plane parallel to the main surface of the substrate 10, are defined as an X direction and a Y direction. A direction orthogonal to the X and Y directions is defined as a Z direction (which is also the stacking direction of a stacked body such as the memory cell array 1).

FIG. 3 is a schematic cross sectional view of the memory cell array 1. FIG. 3 corresponds to a cross section in parallel to the YZ surface in FIG. 2.

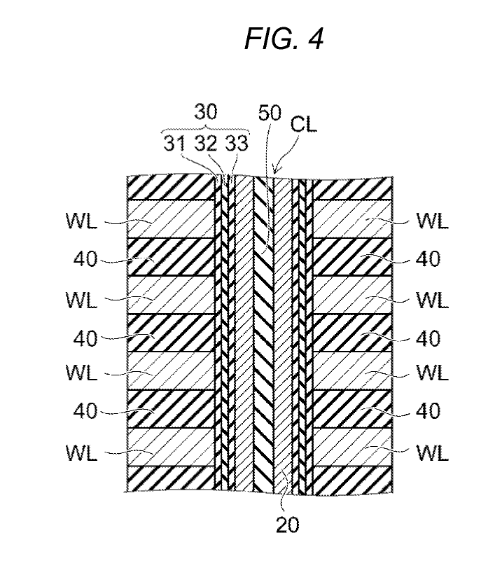

FIG. 4 is an enlarged schematic cross sectional view of a portion of the memory cell of FIG. 3.

The memory cell array 1 comprises a stacked body with a plurality of electrode layers WL and a plurality of insulating layers 40 alternately stacked therebetween.

The stacked body is provided on a back gate BG (electrode) as a lower gate layer. Here, the number of the electrode layers WL shown in the drawings is just an example and the number is arbitrary.

The back gate BG is provided on the substrate 10 on an insulating layer 41, as illustrated in FIG. 3. The back gate BG and the electrode layers WL are a conductive layer, for example, a conductive semiconductor layer. The back gate BG and the electrode layers WL are, for example, silicon layers in which a dopant is added. The insulating layer 40 is a layer mainly including silicon oxide.

The memory cell array 1 includes a plurality of memory strings MS. One memory string MS is formed in a U-shape having a pair of columnar portions CL extending in the Z direction and a joint portion JP jointing the both lower ends of the pair of the columnar portions CL. The columnar portion CL is formed in, for example, a cylindrical shape, penetrating the stacked body.

In one upper end of the pair of the columnar portions CL in the U-shaped memory string MS, a drain side selector gate SGD is provided, while in the other upper end thereof, a source side selector gate SGS is provided. The drain side selector gate SGD and the source side selector gate SGS are provided on the upmost electrode layer WL through the insulating layer 40 as an upper gate layer.

The drain side selector gate SGD and the source side selector gate SGS are conductive layers, for example, semiconductor layers. The drain side selector gate SGD and the source side selector gate SGS are, for example, a silicon layer in which a dopant is added. In the following description, the drain side selector gate SGD and the source side selector gate SGS may be represented simply as a selector gate SG in the following without distinguishing them as a drain or source.

The drain side selector gate SGD and the source side selector gate SGS are separated in the Y direction by an insulative separation film 73. The stacked body under the drain side selector gate SGD and the stacked body under the source side selector gate SGS are separated in the Y direction by an insulative separation film 47. Specifically, the stacked body between the pair of the columnar portions CL in the U-shaped memory string MS is divided by the insulative separation film 47 in the Y direction.

On the selector gate SG, a source line SL and a bit line BL are provided on an insulating layer 48. The source line SL and the bit line BL are, for example, a metal film. As illustrated in FIG. 2, a plurality of bit lines BL are aligned and spaced apart in the X direction and each bit line BL extends in the Y direction. A plurality of source lines SL are aligned and spaced apart in the Y direction and each source line SL extends in the X direction (only one shown in FIG. 3).

A U-shaped memory hole is formed through the stacked body on the back gate BG and the legs of “U” connect across a recess in the back gate BG. A memory film 30 is provided on the inner wall of the memory hole (along the outside of the columnar portion CL and the joint portion). A channel body 20 is provided inside the memory film 30. The channel body 20 is, for example, a silicon film. Dopant concentration of the channel body 20 is lower than the dopant concentration of the electrode layer WL.

Referring to FIG. 4, the memory film 30 is provided between the inner wall of the memory hole and the channel body 20. The memory film 30 includes a block film 31, a charge storage film 32, and a tunnel film 33, as illustrated in FIG. 4. Between the electrode layer WL and the channel body 20, the block film 31, the charge storage film 32, and the tunnel film 33 are provided in this order from the side of the electrode layer WL.

The channel body 20 is formed in a cylindrical shape and the cylindrical memory film 30 is provided so as to cover the outer peripheral surface of the channel body 20. The electrode layers WL surround the channel body 20 through the memory film 30. Further, a core insulating film 50 is provided within the channel body 20.

The block film 31 is in contact with the electrode layers WL, the tunnel film 33 is in contact with the channel body 20, and the charge storage film 32 is provided between the block film 31 and the tunnel film 33.

The channel body 20 operates as a channel in a memory cell, and the electrode layer WL operates as a control gate in the memory cell. The charge storage film 32 operates as a data recording layer for accumulating charges injected from the channel body 20. Namely, a memory cell having a structure where the control gate surrounds a periphery of the channel is formed at each intersection of the channel body 20 and each of the electrode layers WL.

The semiconductor memory device according to the embodiment is a nonvolatile semiconductor memory device capable of erasing and writing data electrically freely and keeping the contents or settings recorded even when the power is turned off.

The memory cell is, for example, a charge trapping memory cell. The charge storage film 32 includes many trap sites for capturing electric charges and it is, for example, a silicon nitride film.

The block film 31 is, for example, a silicon oxide film, a silicon nitride film, or a stacked film including these films. The block film 31 inhibits electric charges accumulated in the charge storage film 32 from diffusing to the electrode layers WL.

The tunnel film 33 becomes a potential barrier when electric charges are injected from the channel body 20 to the charge storage film 32, or when electric charges accumulated in the charge storage film 32 are diffused to the channel body 20. The tunnel film 33 is, for example, a silicon oxide film, a silicon nitride film, a silicon oxynitride film, or a stacked film including these films.

As illustrated in FIG. 2, a drain side select transistor STD is provided on one upper end of the pair of the columnar portions CL in the U-shaped memory string MS and a source side select transistor STS is provided on the other upper end thereof.

The memory cell, the drain side select transistor STD, and the source side select transistor STS are vertical transistors in which a current flows in the Z direction.

The drain side selector gate SGD operates as a gate electrode (control gate) of the drain side select transistor STD. Between the drain side selector gate SGD and the channel body 20, an insulating film 97 (shown in FIG. 3), operating as a gate insulating film of the drain side select transistor STD, is provided. The channel body of the drain side select transistor STD is connected to the bit line BL through a plug 113 above the drain side selector gate SGD.

The source side selector gate SGS operates as a gate electrode (control gate) of the source side select transistor STS. Between the source side selector gate SGS and the channel body 20, an insulating film 98 (shown in FIG. 3) operating as a gate insulating film of the source side select transistor STS is provided. The channel body of the source side select transistor STS is connected to a source line SL through a plug 114 above the source side selector gate SGS.

The back gate transistor BGT is provided in the joint portion JP of the memory string MS. The back gate BG operates as a gate electrode (control gate) of the back gate transistor BGT. The memory film 30 provided within the back gate BG operates as a gate insulating film of the back gate transistor BGT.

Between the drain side select transistor STD and the back gate transistor BGT, there are provided a plurality of memory cells in which the respective electrode layers WL in the respective layers are provided as a control gate. Similarly, between the source side select transistor STS and the back gate transistor BGT, there are also provided a plurality of memory cells in which the respective electrode layers WL in the respective layers are provided as a control gate.

The memory cells, drain side select transistor STD, back gate transistor BGT, and source side select transistor STS are connected in series through the channel body 20, and formed into one U-shaped memory string MS. By arranging the plural memory strings MS in the X direction and the Y direction, the plural memory cells are formed three-dimensionally in the X direction, the Y direction, and the Z direction.

The memory cell array 1 is provided in a memory cell array area on the substrate 10. In the memory cell array area, the plurality of columnar portions CL are arranged in a matrix shape in the X direction and the Y direction, as illustrated in FIG. 1.

FIG. 3 shows the cross section along the line A-A in FIG. 1.

The lower ends of the pair of the columnar portions CL located adjacent to each other in the Y direction with the insulative separation film 47 intervening therebetween are joined, to be formed in a U-shaped memory string MS.

Referring to FIG. 1, the hierarchy selecting unit 2 is provided in an area (hierarchy selection area) outside of the area where the memory cell array 1 is formed (memory cell array area).

The stacked body of the memory cell array 1 is separated into a plurality of blocks 100 (FIG. 1) in the Y direction. The respective blocks 100 extend in the X direction and, at one end thereof, the blocks are connected to the hierarchy selecting units 2 (in the X direction). The insulative separation film 47 is provided between the adjacent blocks 100 in the Y direction.

Blocks 100 connected to the hierarchy selecting units 2 at ends thereof in the X direction alternate with blocks 110 connected to the hierarchy selecting units 2 at the other end thereof in the X direction, such that the connecting end of the blocks 100 extending to the hierarchy selecting units 2 are alternately extend oppositely in the X direction.

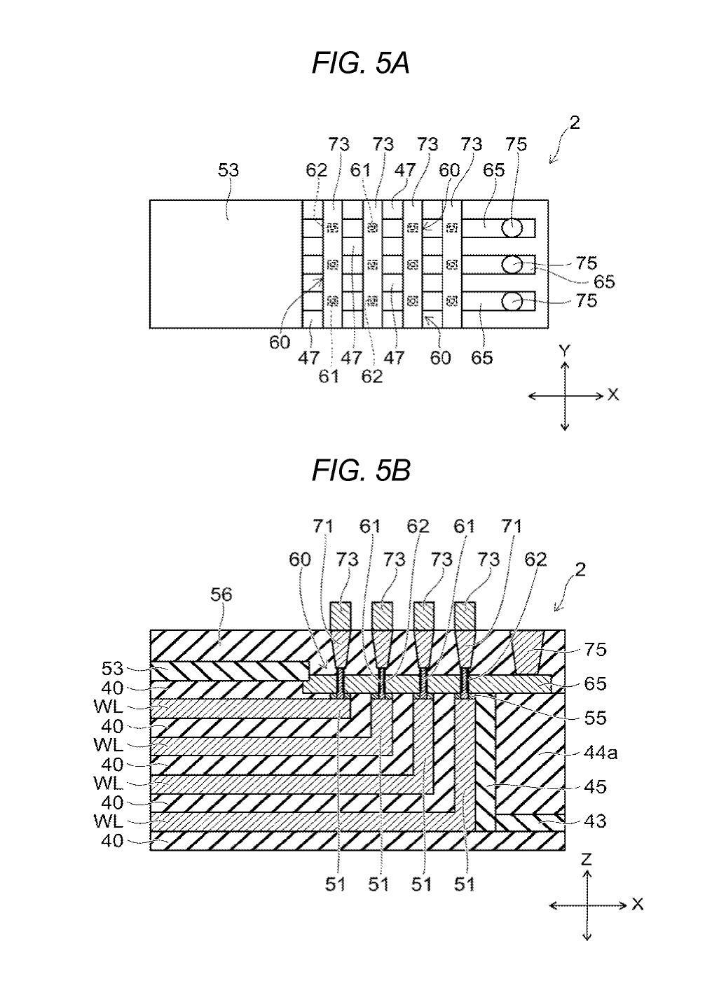

FIG. 5B corresponds to the cross section along the line B-B in FIG. 1.

FIG. 5A is a top plan view of FIG. 5B. In FIG. 5A, an insulating layer 56 shown in FIG. 5B is omitted.

Referring to FIG. 5B, the stacked body, including a plurality of electrode layers WL and a plurality of insulating layers 40, is also provided, i.e., extends into, the hierarchy selection area. An electrode layer WL in the memory cell array 1 and an electrode layer WL in the hierarchy selection area are integrally connected.

In the hierarchy selection area, an electrode layer WL in each layer has an end portion 51. The end portions 51 of the electrode layers WL, other than the uppermost electrode layer WL, are bent upwardly and extend there in the Z direction.

The end portions of the insulating layers 40 between the electrode layers WL are likewise bent upwardly in the hierarchy selection area. The insulating layers 40 are provided between the end portions 51 of the adjacent electrode layers WL in the X direction.

Accordingly, as the distance of the electrode layers WL increases from the upper end of the body shown in FIG. 5B, the end portions 51 of the electrode layers WL thereof are positioned further away from the memory cell array area (the left hand side of FIG. 5B). Thus, the lowermost electrode layer WL has a longer end portion 51 in the Z direction and the length of the electrode layer WL is longer in the X direction. The upper surfaces of the end portions 51 of the respective electrode layers WL are substantially at the same height. The end portion 51 of the lowermost electrode layer WL is adjacent to a wall portion 44a and a side wall film 45 (described below) is provided therebetween.

Word lines 73 are respectively provided on the end portions 51 of the electrode layers WL, as an upper wiring layer. A word line 73 is formed of, for example, a metal film. Between each word line 73 and each end portion 51 of the electrode layer WL, a block selection transistor 60 is provided.

The block selection transistor 60 is, for example, a p-channel type field-effect transistor. It is also a vertical transistor in which a current flows in the Z direction.

The block selection transistor 60 includes a semiconductor body 61, a gate insulating film 62, and a gate electrode 65.

The semiconductor body 61 is provided on the upper surface of the end portion 51 of each electrode layer WL. The semiconductor body 61 is formed in a square columnar shape extending in the Z direction.

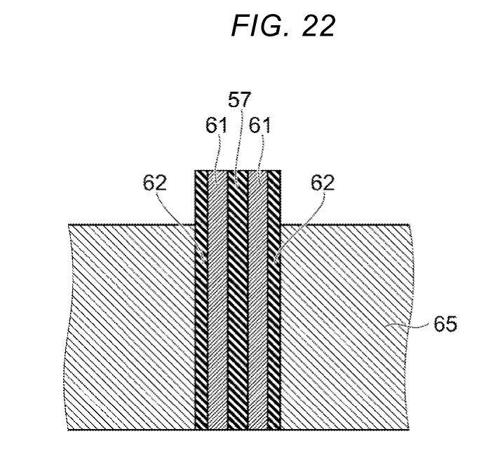

Alternatively, as illustrated in FIG. 22, the semiconductor body 61 may be formed in a cylindrical shape. A core insulating film 57 (FIG. 22) is embedded inside the cylindrical semiconductor body 61. A cylindrical semiconductor body 61 may minimize fluctuation in the channel width and a characteristic variation in the block selection transistor 60 that may be superior to that possible with the square columnar shaped semiconductor body 61. Further, the semiconductor body 61 formed in a cylindrical shape may also improve the cut-off characteristics.

The semiconductor body 61 is, for example, a silicon layer in which a dopant is added. The upper and lower portions of the semiconductor body 61 (relative to the Z direction in FIG. 5B) have a dopant concentration higher than that of the area between the upper and lower portions (in the center of the semiconductor body 61).

In the lower portion of the semiconductor body 61, a source region of the same conductivity type as the electrode layer WL (for example, p type region) is formed, and the lower portion of the semiconductor body 61 is in ohmic contact with the upper surface of the end portion 51 of the electrode layer WL.

Further, in the upper portion of the semiconductor body 61, a drain region of the same conductor type (for example, p type region) is provided as the electrode layer WL is formed. The upper portion of the semiconductor body 61 is in ohmic contact with a plug 71 including, for example, metal. The plug 71 is provided just below the word line 73 and is electrically connected to the word line 73.

The gate insulating film 62 is provided on the side wall of the semiconductor body 61. The gate insulating film 62 surrounds the semiconductor body 61 in a cylindrical manner.

The gate electrode 65 is provided around the gate insulating film 62. The gate electrode 65 faces the side wall of the semiconductor body 61 through the gate insulating film 62. The gate electrode 65 fully surrounds the periphery of the semiconductor body 61 through the gate insulating film 62 in series. Namely, the block selection transistor 60 is a wrap around gate transistor, capable of switching at a low voltage.

The end portion 51 of the electrode layer WL is connected to the word line 73 through the semiconductor body 61 and the plug 71. The block selection transistor 60 switches an electric connection on and off between the electrode layer WL and the word line 73.

A plurality of word lines 73 are formed corresponding to the number of the electrode layers WL. The respective word lines 73 extend in the Y direction.

In the hierarchy selecting unit 2, the stacked body, including the plural electrode layers WL, is also separated into a plurality of blocks in the Y direction. Between the blocks, an insulative separation film 47 is provided, as illustrated in FIG. 5A.

The semiconductor body 61 and the plug 71 are provided in each of the end portions 51 of the electrode layers WL in series in each block.

A plurality of gate electrodes 65 are formed corresponding to the number of the blocks of the stacked body. The respective gate electrodes 65 extend in the X direction. The plug 75 including, for example, a metal is provided on the end portion of each gate electrode 65 in the X direction. The gate electrode 65 is connected to agate wiring, not illustrated, through the plug 75.

An insulating layer 56 is provided between the upper surface of the gate electrode 65 and the plugs 71 of the word lines 73, and the gate electrode 65 is insulated from the word lines 73.

The insulating layer 40 is provided between the lower surface of the gate electrode 65 and the upper surfaces of the end portions 51 of the electrode layers WL, so that the gate electrode 65 is insulated from the electrode layers WL.

The word lines 73 are provided to commonly electrically connect the electrode layers WL across a plurality of blocks. The gate electrode 65 is provided in every block. The gate electrode 65 is provided to provide agate for the semiconductor bodies 61 in each block.

The gate electrode 65 extends in a direction crossing the word line 73 (X direction). The semiconductor bodies 61 are arranged in a matrix shape at each intersection of the word lines 73 and the gate electrodes 65.

In the semiconductor memory device according to the embodiment described above, the drain side select transistor STD switches an electrical current between the bit line BL and the channel body 20. The source side select transistor STS switches an electrical current between the source line and the channel body 20.

In other words, when a predetermined potential is applied to the drain side selector gate SGD, the channel body 20 may be electrically connected to the bit line BL. When a predetermined potential is applied to the source side selector gate SGS, the channel body 20 may be electrically connected to the source line SL.

Further, when a predetermined potential is applied to the back gate BG, the back gate transistor BGT is turned on, and the channel body 20 of a pair of the columnar portions CL conducts electricity through the channel body 20 of the joint portion JP.

Further, a hierarchy of the electrode layer WL is selected by the word line 73. Further, the block 100 of the electrode layers WL is selected by the block selection transistor 60.

According to the embodiment, the block selection transistor 60 is a p-channel typed field-effect transistor of a normally-on type. Namely, in a state where the gate electrode 65 is at 0 V, a p-channel is formed in the semiconductor body 61 and the potential of the word line 73 is provided to the electrode layer WL through the plug 71 and the semiconductor body 61.

For example, a data erasing operation will be described. In a semiconductor memory device having a general two dimensional structure, by raising the substrate potential, electrons injected in a floating gate are pulled out. However, in the semiconductor memory device having a three dimensional structure according to the embodiment, the channel of a memory cell is not directly connected to a substrate. Therefore, there is proposed a method of boosting the channel potential of the memory cell by using a Gate Induced Drain Leakage (GIDL) current generated in a channel in the end of the selector gate SG.

Namely, a hole generated by applying a high voltage to a high concentration dopant diffusion area formed in the channel body in a vicinity of the upper end portion of the selector gate SG is supplied to the channel body 20, hence to raise the channel potential. By setting the potential of the electrode layer WL, for example, at the ground potential (0 V), the electrons of the charge storage film 32 are pulled out due to a potential difference between the channel body 20 and the electrode layer WL, or the hole is injected to the charge storage film 32, hence to perform the erasing operation.

Erasing by the block unit including a plurality of memory strings MS is proposed. In this case, an erasing potential is also given to an electrode layer WL of a non-selected memory cell that is not a target for erasing. According to an increase in the number of stacks of the electrode layers WL, the size of one block is increased, and the number of the non-selected memory cells on which a voltage stress is imposed at an erasing time is increased, which increases a possibility of causing a read-disturbance where the proper setting of the memory cells is disturbed.

However, according to the embodiment, the block selection transistors 60 may independently control (turn on and off) the individual corresponding blocks 100. By turning off the block selection transistor 60 for the electrode layers WL in a non-selected block 100, a current flowing between the end portions 51 of the electrode layers WL and the word lines 73 may be terminated.

In the related art, a large block unit including a plurality of the blocks 100 shown in FIG. 1 is collectively erased, while according to the embodiment, erasing may be performed in each selected block 100, and the erasing unit size may be reduced. Therefore, the number of times of imposing a voltage stress on a non-selected memory cell at an erasing time may be reduced. As the result, a read-disturb may be minimized, and the reliability of the semiconductor memory device may be improved.

Since the block selection transistor 60 is a p-channel type field-effect transistor that is the type that is normally on, the p-channel layer of the semiconductor body 61 may be diminished by applying a positive potential of a threshold value, or more, to the gate electrodes 65 in a non-selected block. The potential of the electrode layers WL, shut off from the word lines 73, in the non-selected block is changed to a floating state, and between each of the electrode layers WL and each of the channel bodies 20, there is no potential difference that pulls out the electrons from the electrode layer WL because of a potential increase in the same electrode layer WL through coupling with the corresponding channel body 20.

Since the block selection transistor 60 is a p-channel type field-effect transistor that is normally on, a negative voltage generating circuit for driving the block selection transistor 60 is not necessary. Therefore, a peripheral circuit (circuit for driving and controlling the memory cell array 1) may be reduced in size and area.

A gate electrode is not necessary for the number of the electrode layers WL in every block, but only one common gate electrode 65 has to be provided for each block, so that the peripheral circuit may be reduced in size and area.

The cut-off characteristic of the block selection transistor 60 depends on the dopant concentration of the semiconductor body 61. The dopant concentration of the semiconductor body 61 may be set separately from the dopant concentration of the electrode layer WL, and therefore, desired cut-off characteristics may be given to the block selection transistor 60.

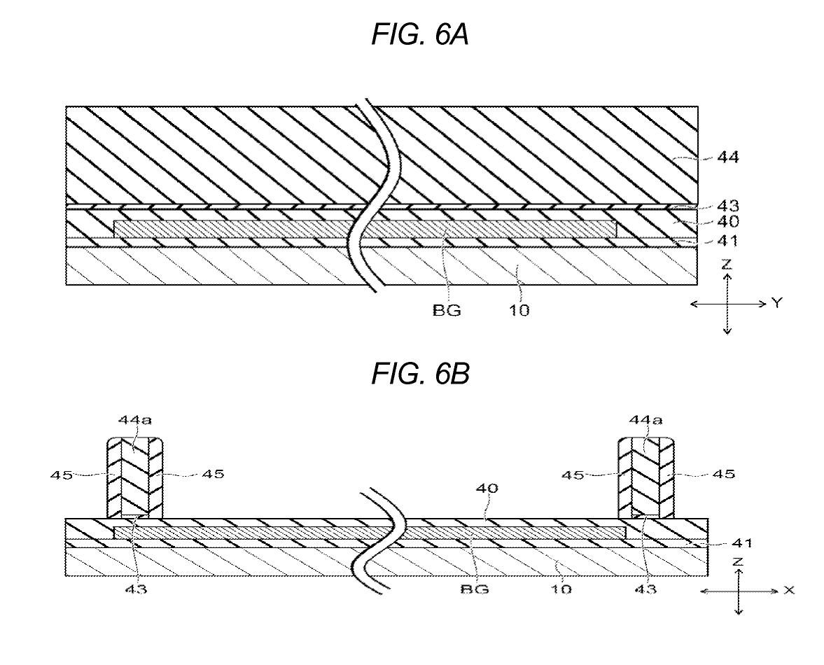

Next, a method of forming the hierarchy selecting unit 2 and the block selection transistor 60 will be described with reference to FIGS. 6A to 17B.

As illustrated in FIG. 6A, a back gate BG is formed on the substrate 10 on an insulating layer 41. An insulating layer 40 is formed on the back gate BG.

An insulating layer 44 is formed on the insulating layer 40, which is formed on an insulating film 43. The insulating film 43 is a film of a material different from that of the insulating layer 40 and the insulating layer 44. For example, the insulating layer 40 and the insulating layer 44 are a silicon oxide film, while the insulating film 43 is a silicon nitride film.

Next, as illustrated in FIG. 6B, the insulating layer 44 is processed according to, for example, Reactive Ion Etching (RIE) using a resist mask that is not illustrated. The insulating film 43 under the insulating layer 44 operates as an etch stop film for this etching step.

The insulating layer 44 in the memory cell array area is then removed. The insulating layer 44 is left in the hierarchy selection area outside the memory cell array area as the wall portion 44a.

The wall portion 44a extends in the Y direction (a direction perpendicular to (into and out of) the paper surface in FIG. 6B). The aspect ratio of the wall portion 44a (ratio of a height in the Z direction per a width in the X direction) is 1 or more. Further, the ratio of the area where the wall portion 44a is formed compared to the whole chip area is less than 1%.

After the wall portion 44a is formed, a blanket film is provided to form a side wall film 45 that is conformably formed along the side surface and the upper surface of the wall portion 44a (the film may cover the whole surface, a portion of which is etched away in a later step). The side wall film 45 is a film different from the wall portion 44a and, for example, a silicon nitride film.

After the side wall film 45 is conformably formed, other portions of the blanket film are etched back. According to this, the blanket film that may cover the upper surface of the wall portion 44a and the insulating layer 40 are removed, and the side wall film 45 is left on the side wall of the wall portion 44a as shown in FIG. 6B. The insulating film 43 that is a silicon nitride film, similarly to the side wall film 45, is also removed from the upper surface of the insulating layer 40. The insulating film 43 under the wall portion 44a is left in place.

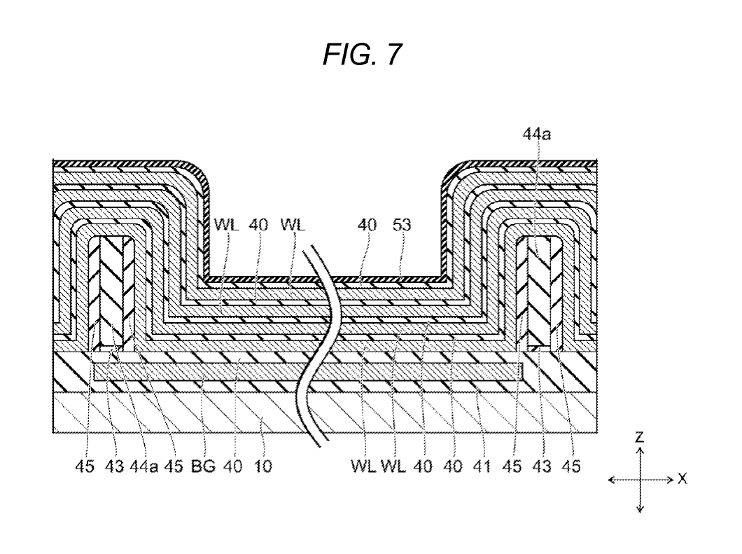

Next, as illustrated in FIG. 7, electrode layers WL and insulating layers 40 are alternately formed on the insulating layer 40. Further, on the uppermost layer of the stacked body, an insulating film 53 is formed. The insulating film 53 is a film different from the insulating layer 40 positioned under the above film. For example, the insulating layer 40 is a silicon oxide film and the insulating film 53 is a silicon nitride film. The electrode layer WL is a silicon layer, for example, doped with boron.

The electrode layer WL, the insulating layer 40, and the insulating film 53 are formed by, for example, a Chemical Vapor Deposition (CVD) process.

A film stack including the electrode layer WL, the insulating layer 40, and the insulating film 53 is formed along the side surface of the wall portion 44a (side wall film 45), and further formed above the upper surface of the wall portion 44a.

In the electrode layers WL and the insulating layers 40, portions adjacent to the side surface of the wall portion 44a (side wall film 45) are bent upwardly and extend in a height direction (the Z direction) of the wall portion 44a.

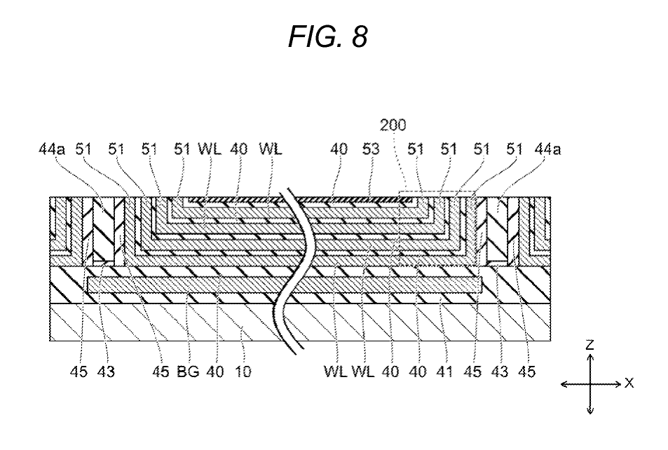

Next, the film stack is made flat, for example, by employing a Chemical Mechanical Polishing (CMP) process. As illustrated in FIG. 8, the CMP process stops at the insulating film 53 that is positioned in an area where the electrode layers WL are formed in parallel to the substrate 10 and are not bent. The insulating film 53 thus operates as a CMP stop film.

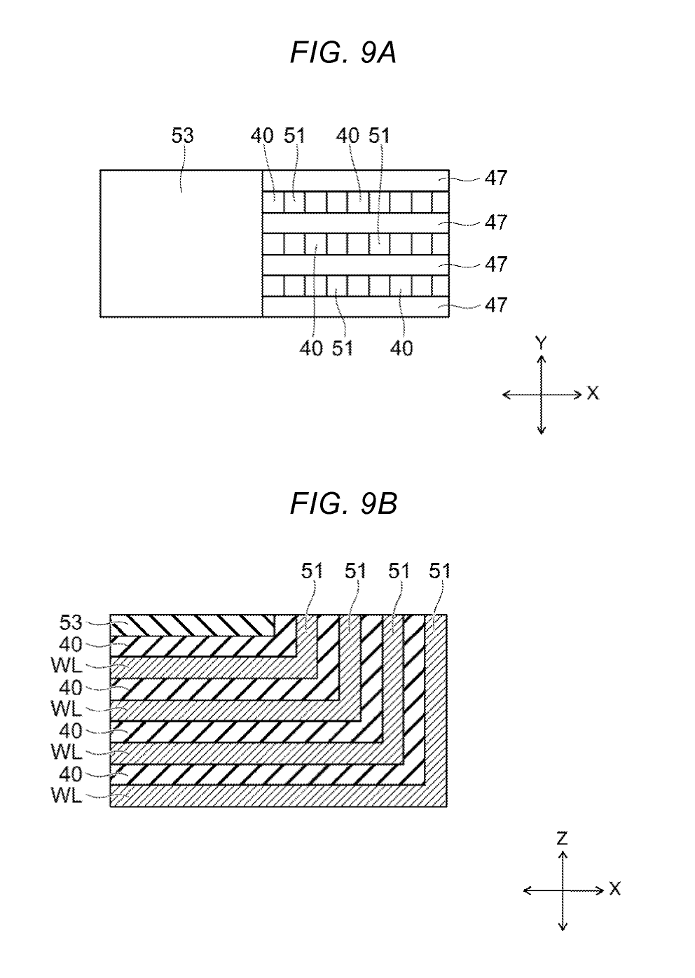

FIG. 9B is an enlarged cross sectional view of a portion 200 surrounded by a dashed line in FIG. 8.

FIG. 9A is a top plan view of FIG. 9B.

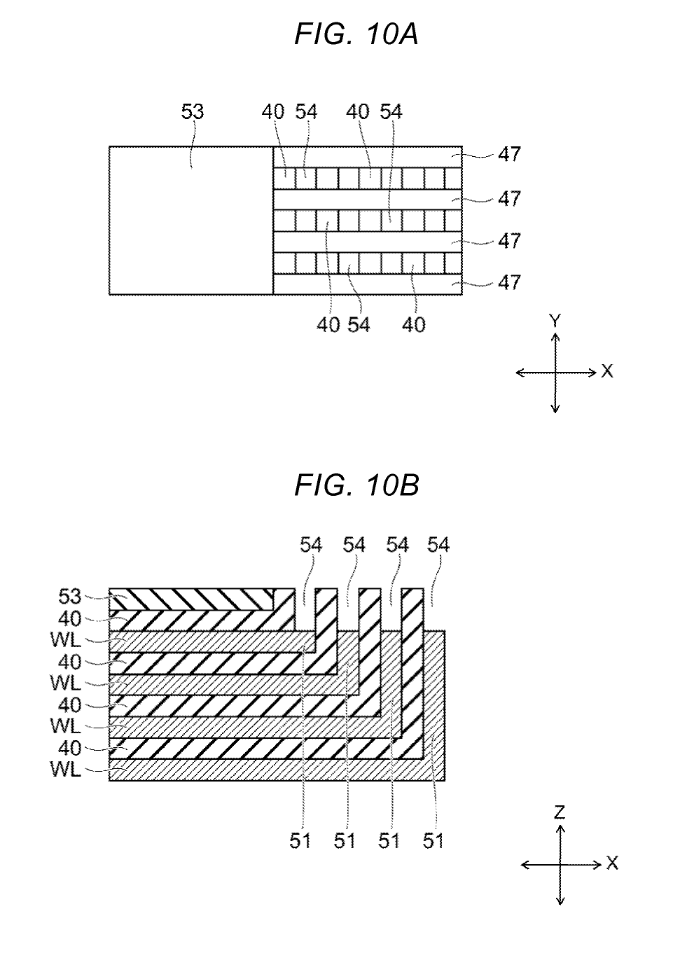

FIGS. 10B, 11B, 12B, 13B, 14B, 15B, 16B, and 17B show the same cross section al view as that of FIG. 9B.

Further, FIGS. 10A, 11A, 12A, 13A, 14A, 15A, 16A, and 17A respectively show the top plan views of FIGS. 10B, 11B, 12B, 13B, 14B, 15B, 16B, and 17B.

As illustrated in FIG. 9A, the stacked body including the plural electrode layers WL is separated into a plurality of blocks by the insulative separation films 47 in the Y direction. In each block, the upper surfaces of the end portions 51 of the electrode layers WL are separated by the insulating layers 40 in the X direction. Accordingly, the upper surfaces of the end portions 51 of the electrode layers WL are arranged in a matrix shape in the X direction and the Y direction.

Next, the upper surfaces of the end portions 51 of the electrode layers WL are recessed using, for example, an RIE (reactive ion etch) process. As a result, as illustrated in FIGS. 10A and 10B, a space 54, surrounded by the insulating layers 40 and the insulative separation films 47, is formed above each end portion 51 of each electrode layer WL.

Here, the end portion 51 of the uppermost electrode layer WL does not have an upwardly-bent portion in the example shown in FIG. 10B but the upwardly-bent portion may optionally be provided.

As a result of the CMP process in the previous step, as illustrated in FIG. 9A, the upper surfaces of the end portions 51 of the respective electrode layers WL are aligned at the same height. Then, by simultaneously etching all the end portions 51 of the electrode layers WL, the recessed amounts of the end portions 51 of all the electrode layers WL may be made to be uniform. In other words, the heights of the respective spaces 54 may be set through this etching. In the space 54, a semiconductor body 61 of the block selection transistor 60 is formed as described below. Accordingly, the lengths of the respective semiconductor bodies 61 in the Z direction (channel length of the block selection transistor 60) may be the same, thereby restraining a characteristic variation in the block selection transistors 60.

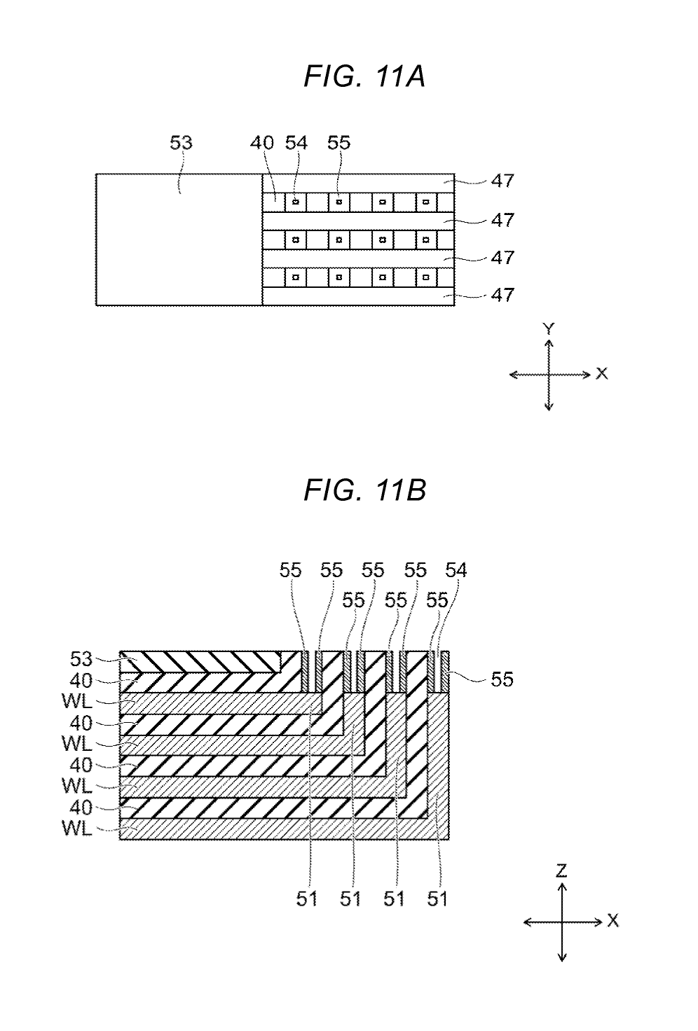

Next, as illustrated in FIGS. 11A and 11B, a spacer film 55 is formed within the space 54. The spacer film 55 is, for example, a silicon oxide film.

The spacer film 55 is conformably formed within the space 54 and then, the spacer film 55 in the bottom of the space 54 is removed according to the RIE process. The spacer film 55 is thus formed cylindrically on the side wall of the space 54.

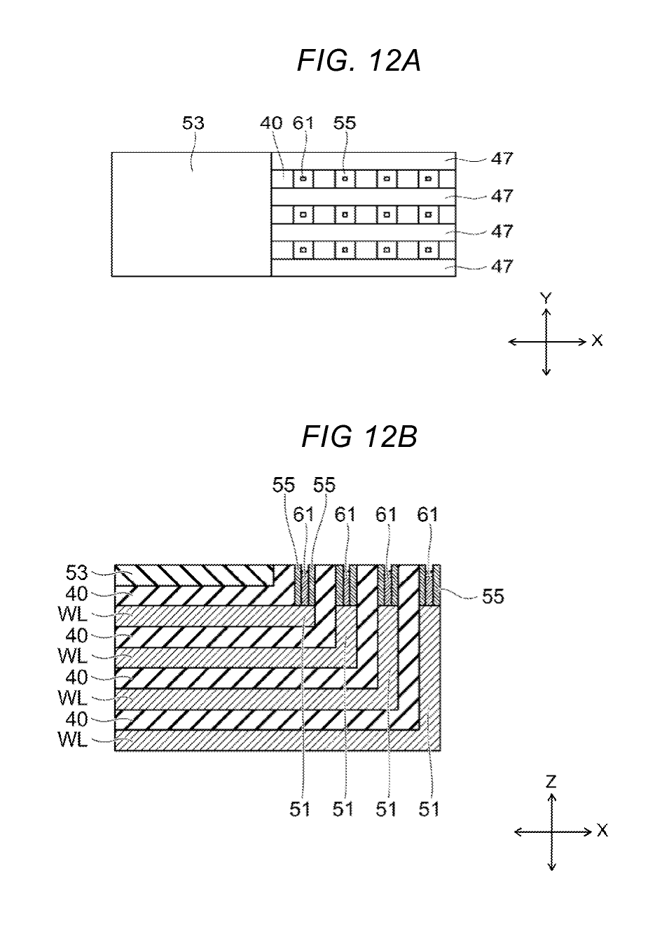

Then, as illustrated in FIGS. 12A and 12B, a semiconductor body 61 is embedded inside the spacer film 55 and the upper portion of the semiconductor body 61 is etched and recessed.

The semiconductor body 61 is a silicon film of the same conductivity type as that of the electrode layer WL. The semiconductor body 61 is, for example, a p-type silicon film doped with boron.

An area in the upper and lower portions of the semiconductor body 61 is doped to a higher dopant concentration than the dopant concentration in an area between the upper portion and the lower portion of the semiconductor body 61.

In the lower portion of the semiconductor body 61 in contact with the end portion 51 of the electrode layer WL, a source region is formed by implanting a dopant (boron), for example by an ion implantation process. Alternatively, a dopant (boron) may be diffused from the end portion 51 of the electrode layer WL to the lower portion of the semiconductor body 61.

Further, in the upper portion of the semiconductor body 61 (in contact with the plug 71 of FIG. 5B), a drain region is formed by implanting a dopant (boron), for example, using an ion implantation process.

As the semiconductor body 61, a polycrystalline silicon film is formed, for example, using a CVD process.

Alternatively, the semiconductor body 61 is a silicon film which is epitaxially grown from the end portion 51 of the electrode layer WL. In this case, mobility in the film may be enhanced.

Alternatively, the semiconductor body 61 is a silicon germanium. In this case, a crystallization temperature may be lowered.

Alternatively, the semiconductor body 61 is a silicon carbide. In this case, a breakdown voltage may be increased.

Further, a metal silicide may be formed between the end portion 51 of the electrode layer WL and the lower portion (source region) of the semiconductor body 61.

Here, the electrode layer WL is not restricted to a silicon layer but it may be a metal layer. In this case, the source region and the drain region of the semiconductor body 61 may be either conductivity type (p-type or n-type).

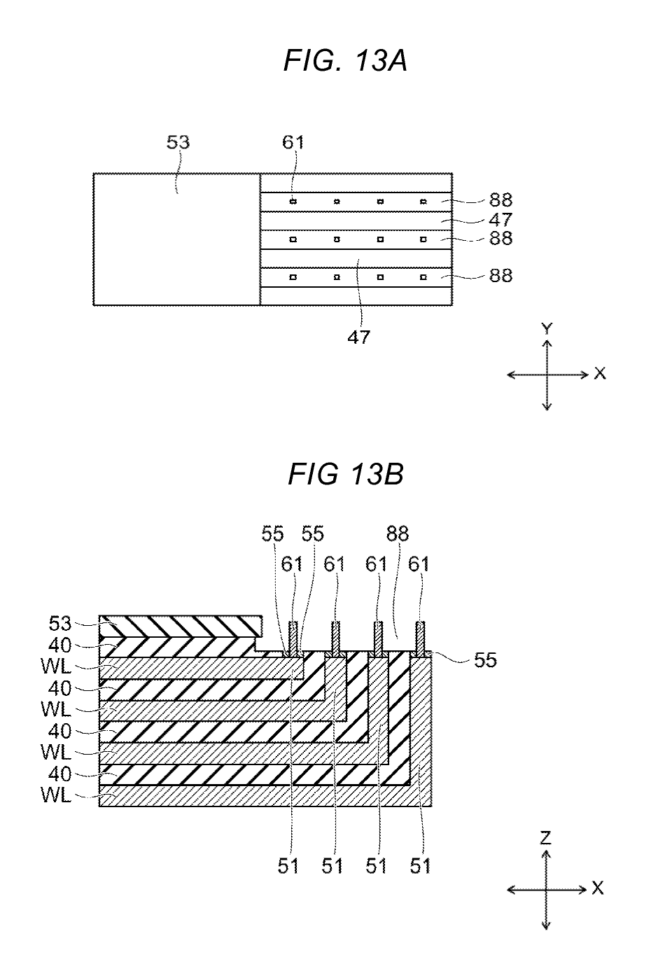

Next, for example, according to the wet etching process, the spacer film 55 is removed. The insulating layer 40 adjacent to the spacer film 55 in the X direction is the same material as the spacer film 55, for example, a silicon oxide film, and therefore, a part of the insulating layer 40 is also removed according to the wet etching. Through this wet etching, as illustrated in FIGS. 13A and 13B, a groove 88 extending in the X direction is formed around the semiconductor body 61 and between the semiconductor bodies 61 adjacent in the X direction. A plurality of grooves 88 are aligned in the Y direction with the insulative separation film 47, respectively, interposed therebetween.

Here, the side wall film 45, which is a silicon nitride film, provided on the side wall of the above mentioned wall portion 44a protects the wall portion 44a from the above wet etching.

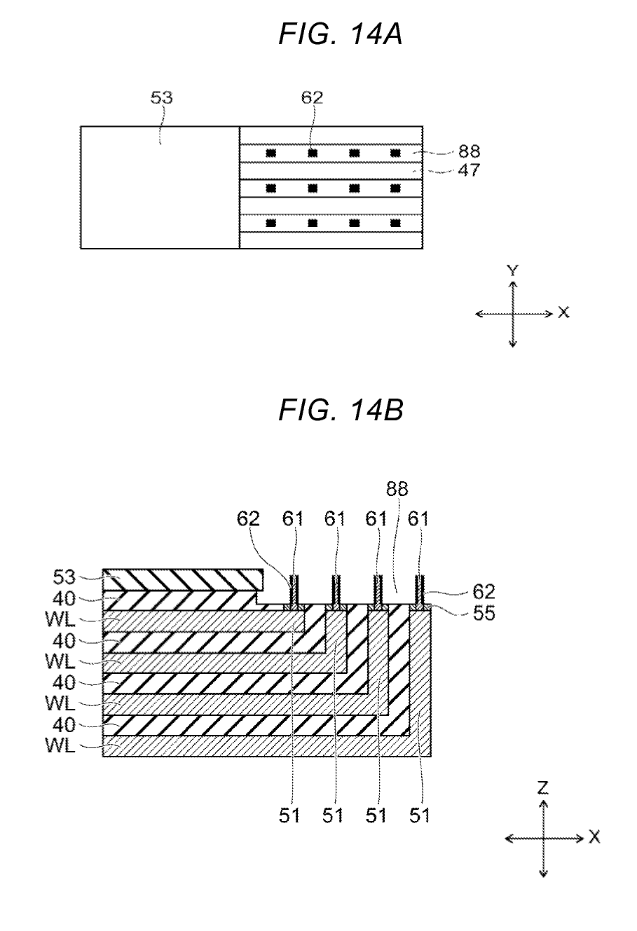

When the spacer film 55 and the insulating layer 40 adjacent to the spacer film 55 in the X direction are removed, the side wall of the semiconductor body 61 is exposed. Around the side wall of the semiconductor body 61, a gate insulating film 62 is formed, as illustrated in FIGS. 14A and 14B. The gate insulating film 62 is also formed on the upper surface of the semiconductor body 61. The gate insulating film 62 is, for example, a silicon oxide film.

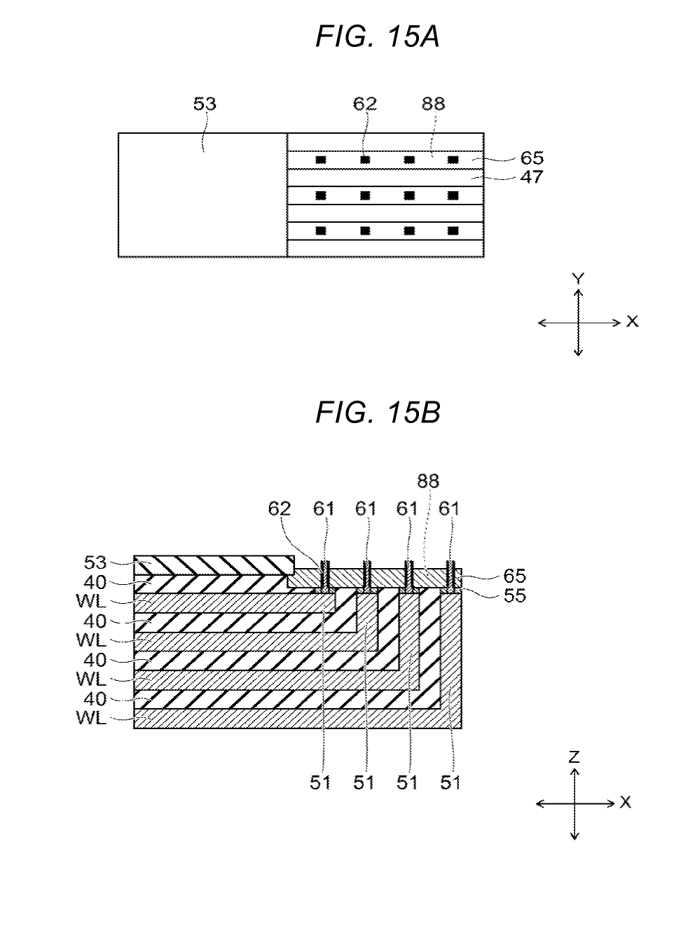

After the gate insulating film 62 is formed, the gate electrode 65 is embedded in the groove 88, as illustrated in FIGS. 15A and 15B. As the gate electrode 65, for example, a silicon film doped with boron is formed using a CVD process.

The upper surface side of the gate electrode 65 is recessed by the RIE process, and the upper portion of the semiconductor body 61 protrudes from the gate electrode 65. The gate insulating film 62 on the upper surface of the semiconductor body 61 is removed.

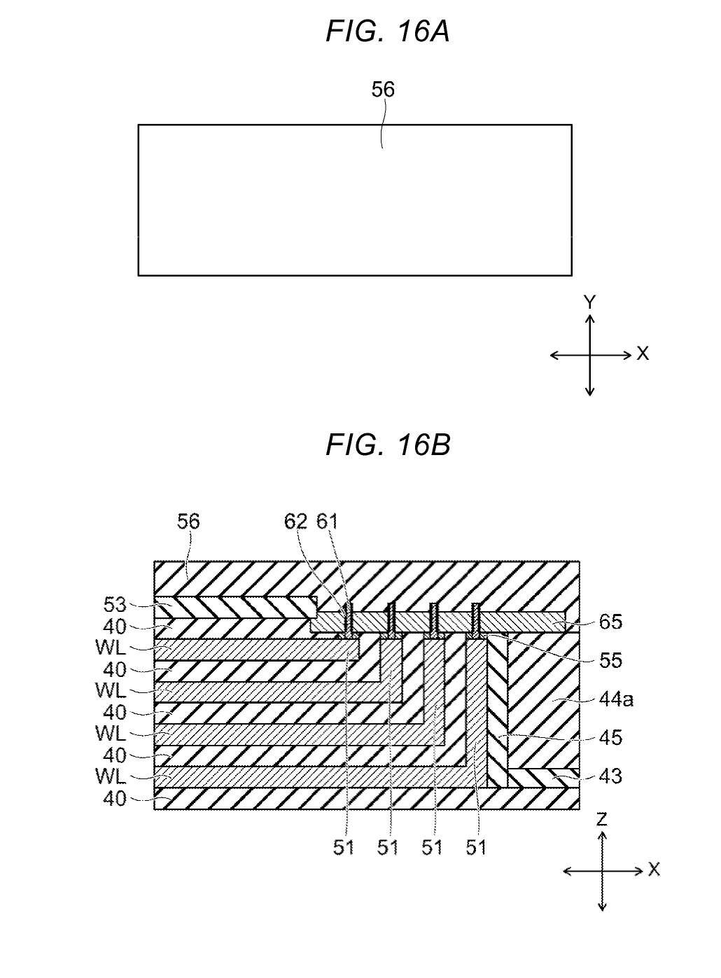

So as to cover the protruding upper portion of the semiconductor body 61, an insulating layer 56 is formed on the gate electrode 65, as illustrated in FIGS. 16A and 16B. The insulating layer 56 is also formed on the insulating film 53 and the insulative separation film 47.

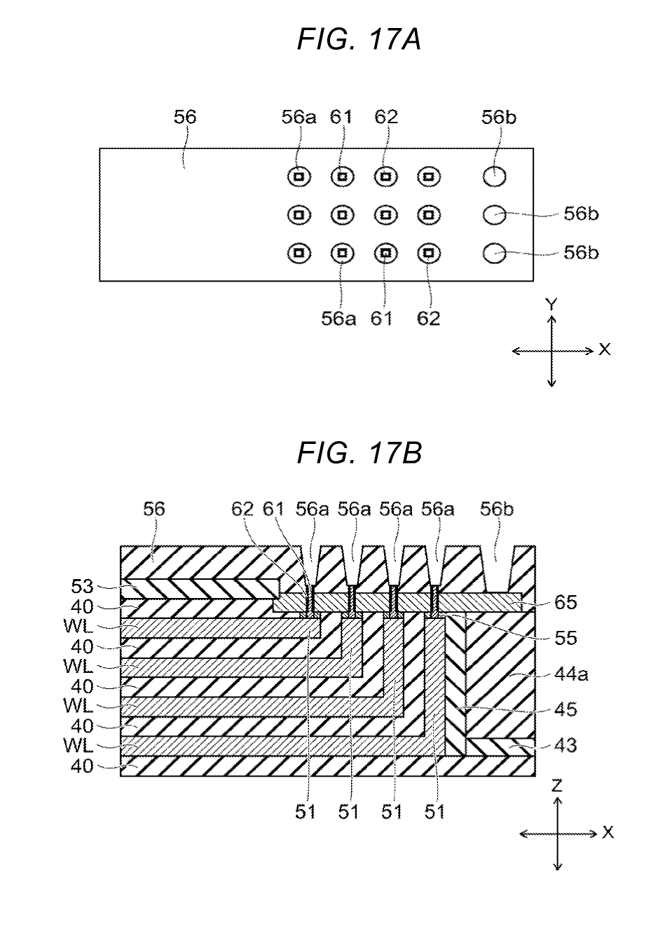

As illustrated in FIGS. 17A and 17B, a plurality of holes 56a and 56b are formed in the insulating layer 56. The hole 56a penetrates through the insulating layer 56, to reach the semiconductor body 61. The hole 56b penetrates through the insulating layer 56, to reach the gate electrode 65.

A metal is embedded in the holes 56a and 56b. According to this, as illustrated in FIGS. 5A and 5B, a plug 71 connected to the semiconductor body 61, and a plug 75 connected to the gate electrode 65 are formed.

The upper layer wirings are respectively formed on the plugs 71 and 75. A word line 73 is formed on the plug 71 and a gate line, not illustrated, is formed on the plug 75.

In the stacked body in the memory cell array area, after each U-shaped memory hole is formed, the above mentioned memory film 30 and channel body 20 are formed within the memory hole.

In order to form a U-shaped memory hole, a concave portion is previously formed in the back gate BG and a sacrificial film is embedded within the concave portion. Then, a stacked body including the plural electrode layers WL is formed on the back gate BG.

After forming the stacked body, a hole extending in a stacking direction of the stacked body (the Z direction) is formed. Then, the hole reaches the sacrificial film, the sacrificial film is etched and removed through the hole, and a pair of holes is connected to the concave portion, thereby to form a U-shaped memory hole. The channel body 20 is formed within the memory hole through the memory film 30.

When the number of the electrode layers WL is large, the stacked body may be formed in several divided parts in order to decrease a difficulty of the process.

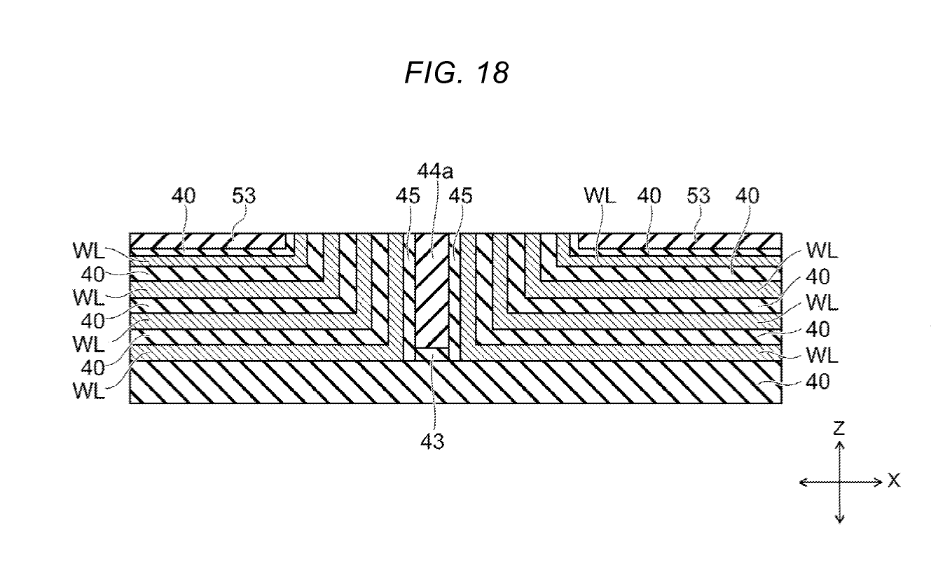

At first, the process shown up to FIG. 18 is performed similarly to the above mentioned FIGS. 6A to 8. FIG. 18 corresponds to the cross sectional view of the process in FIG. 8.

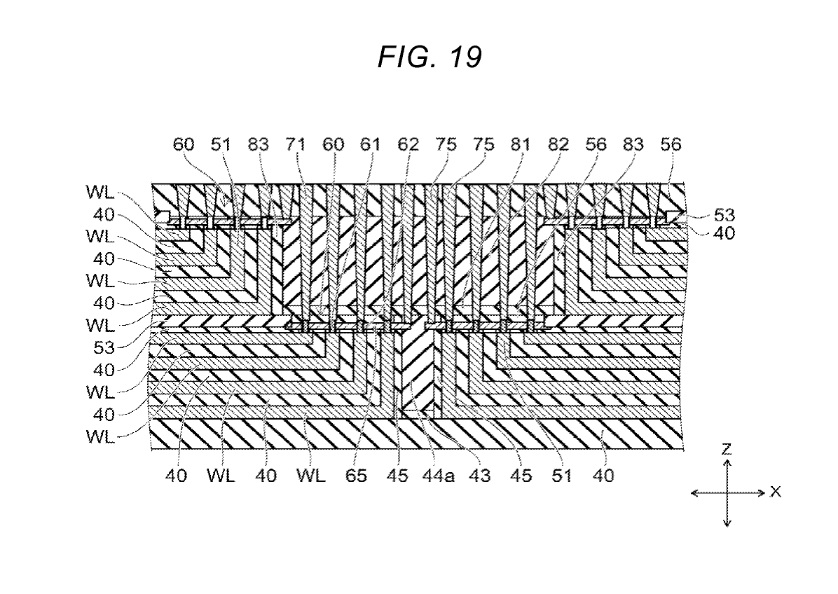

Then, in the same process as mentioned above, a block selection transistor 60 is formed. In the structure body, an insulating layer 82 is formed through an insulating film 81 shown in FIG. 19. The insulating layer 82 is processed to be left as a wall portion. On the side wall of the wall portion 82, a side wall film 83 is formed. For example, the wall portion 82 is a silicon oxide film, and the insulating film 81 and the side wall film 83 are a silicon nitride film.

The wall portion 82 is formed on the wall portion 44a of the lower layer and the block selection transistor 60 of the stacked body of the lower layer.

Then, a stacked body is further formed on the lower stacked body so as to run upon the wall portion 82. Accordingly, also in an area adjacent to the wall portion 82 in the upper stacked body, the end portions 51 of the electrode layers WL bent upwardly are formed, extending in the Z direction.

Hereinafter, similarly to the above mentioned embodiment, also on the end portions 51 of the electrode layers WL in the upper stacked body, the block selection transistors 60 are formed, and on the block selection transistors 60, the insulating layer 56 is formed.

Then, the plugs 71 and 75 are formed. The plug 71 reaching the semiconductor body 61 of the block selection transistor 60 on the lower layer side and the plug 75 reaching the gate electrode 65 of the block selection transistor 60 on the lower layer side penetrate the wall portion 82 of the upper layer.

In the structure where the end portions 51 of the electrode layers WL and the insulating layers 40 between the end portions 51 extend in a direction vertical to the main surface of the substrate 10 (shown in FIGS. 2 and 3), when a film thickness of the electrode layer WL and the insulating layer 40 is thin, a distance between the end portions 51 may become too narrow to conform to the design rule of the plug 71, or a proper distance may not be obtained between the adjacent block selection transistors 60 in some cases.

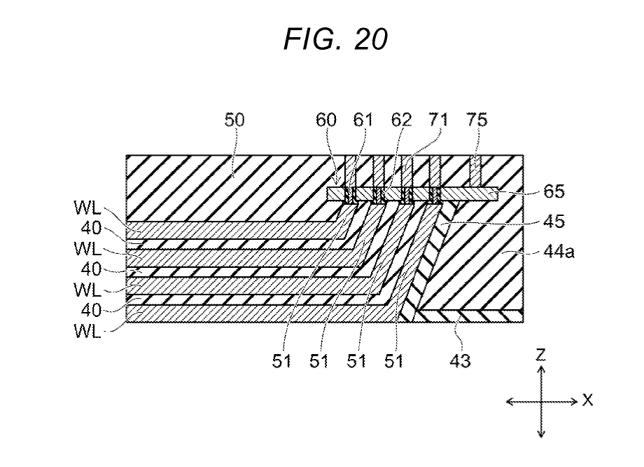

Then, as illustrated in FIG. 20, by inclining or angling the end portions 51 of the electrode layers WL and the insulating layers 40 between the end portions 51 with respect to the main surface of the substrate 10 (shown in FIGS. 2 and 3) and the stacking direction (the Z direction), a width of the upper surface of the end portion 51 in the X direction may be greater than the film thickness of the electrode layer WL. Further, a width of the upper surface of the insulating layer 40 between the end portions 51 in the X direction, in other words, a distance between the end portions 51 may be greater than the film thickness of the insulating layer 40.

This makes it easy to conform to the design rule of the plug 71 and makes it possible to establish spacing between the block selection transistors 60, thereby improving yield.

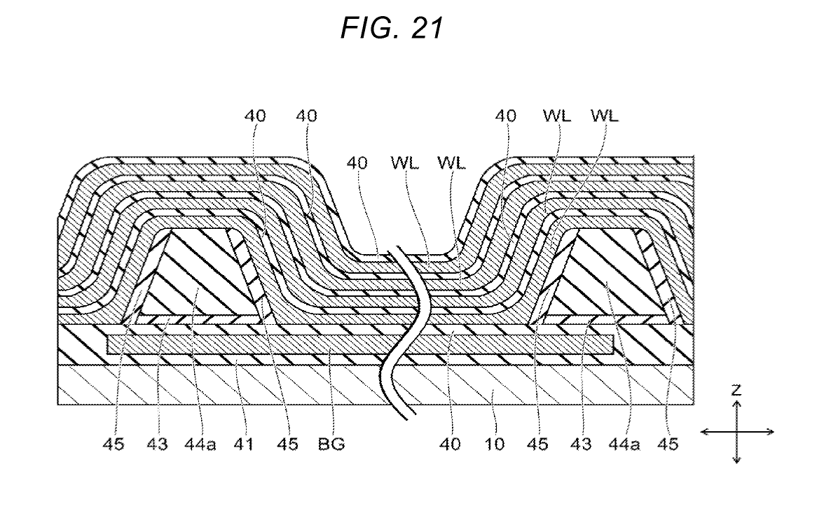

As illustrated in FIG. 21, by forming the wall portion 44a so that the cross sectional shape of the wall portion 44a may be a trapezoid, the electrode layers WL and the insulating layers 40 are formed at an angle or are inclined with respect to the main surface of the substrate 10 along the inclination of the side wall (the side wall film 45 formed on the side wall of the wall portion 44a) of the wall portion 44a.

In the above mentioned embodiment, the U-shaped memory string MS with the lower ends of the pair of the columnar portions CL connected within the back gate BG that is the lower gate layer has been described. The memory string, however, may be formed in an I-shaped, i.e., straight line structure penetrating the lower gate layer (lower selector gate), the stacked body including the plural electrode layers WL stacked on the lower gate layer, and the upper gate layer (upper selector gate) provided on the stacked body.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form according to the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a substrate;
a stacked body formed by a plurality of electrode layers and a plurality of insulating layers alternately stacked on the substrate, including a memory cell array area and a hierarchy selection area provided outside of the memory cell array area;
a channel body which extends into the stacked body in a stacking direction of the stacked body in the memory cell array area;
a memory film provided between the electrode layers and the channel body;
a plurality of word lines provided on the stacked body in the hierarchy selection area; and
a block selection transistor provided between the stacked body and the word line in the hierarchy selection area, wherein
each of the electrode layers includes an end portion extending toward the block selection transistor in the hierarchy selection area, and
the block selection transistor includes
a plurality of semiconductor bodies which respectively extend from the end portions of the respective electrode layers to the respective word lines,
a plurality of gate insulating films which are provided on side walls of the respective semiconductor bodies; and
a plurality of gate electrodes which face the side walls of the respective semiconductor bodies through the gate insulating films.

2. The device according to claim 1, wherein
the block selection transistor is a normally on type field-effect transistor.

3. The device according to claim 2, wherein
the stacked body in the memory cell array is divided into a plurality of blocks extending in a first direction in a plane parallel to the substrate, and
a plurality of the gate electrodes are respectively provided for each block.

4. The device according to claim 2, wherein
the stacked body in the memory cell array is divided into a plurality of blocks extending in a first direction in a plane parallel to the substrate, and
the end portions of the electrode layers in each block in the first direction are connected to the block selection transistor.

5. The device according to claim 4, wherein
the plurality of blocks include a first block with an end thereof in the first direction connected to the block selection transistor and a second block connected to the block selection transistor in the first direction on an opposing end thereof, and
the first block and the second block are alternately arranged in a second direction that is orthogonal to the first direction.

6. The device according to claim 1, wherein
the stacked body in the memory cell array is divided into a plurality of blocks extending in a first direction in a plane parallel to the substrate, and
a plurality of the gate electrodes are provided for each block.

7. The device according to claim 1, wherein
the stacked body in the memory cell array is divided into a plurality of blocks extending in a first direction in a plane parallel to the substrate, and
the end portions of the electrode layers in each block in the first direction are connected to the block selection transistor.

8. The device according to claim 1, wherein
the plurality of blocks include a first block with an end thereof in the first direction connected to the block selection transistor and a second block connected to the block selection transistor in the first direction on an opposing end thereof, and
the first block and the second block are alternately arranged in a second direction that is orthogonal to the first direction.

9. The device according to claim 1, wherein
each of the plurality of semiconductor bodies includes a silicon material with a dopant.

10. The device according to claim 9, wherein
each of the plurality of semiconductor bodies has an upper portion electrically connected the word line and a lower portion electrically connected the end portion of the electrode layer, and
a dopant concentration of the upper portion is higher than a dopant concentration of an area between the upper portion and the lower portion.

11. The device according to claim 9, wherein
each of the plurality of semiconductor bodies has an upper portion electrically connected the word line and a lower portion electrically connected the end portion of the electrode layer, and
a conductive type of the lower portion is same as a conductive type of the electrode layer.

12. The device according to claim 9, wherein
each of the plurality of semiconductor bodies has an upper portion electrically connected the word line and a lower portion electrically connected the end portion of the electrode layer, and
a conductive type of the upper portion is same as a conductive type of the word line.

13. A semiconductor memory device comprising:
a substrate having a surface in a first plane;
a memory cell array comprising a plurality of electrode layers alternating with a plurality of insulating layers stacked on the substrate;
a memory cell array area and a hierarchy selection area provided outside of and adjacent to the memory cell array area;
a channel body which extends into the memory cell array in a direction orthogonal to the first plane;
a memory film provided between each of the electrode layers and the channel body;
a plurality of word lines provided on the memory cell array in electrical communication with the hierarchy selection area; and
a block selection transistor provided between the memory cell array and the word lines in the hierarchy selection area, wherein
each of the electrode layers includes an angled end portion extending toward the block selection transistor in the hierarchy selection area, and
the block selection transistor includes
a plurality of semiconductor bodies which respectively extend from the end portions of the respective electrode layers to the respective word lines,
a plurality of gate insulating films which are provided on side walls of the respective semiconductor bodies; and
a plurality of gate electrodes which face the side walls of the respective semiconductor bodies through the gate insulating films.

14. The device according to claim 13, wherein
the block selection transistor is a normally-on type field-effect transistor.

15. The device according to claim 14, wherein
the memory cell array is divided into a plurality of blocks extending in a first direction in a plane parallel to the first plane.

16. The device according to claim 15, wherein
a gate electrode is provided for each block.

17. The device according to claim 13, wherein
the memory cell array is divided into a plurality of blocks extending in a plane parallel to the first plane.

18. The device according to claim 17, wherein
the end portions of the electrode layers in each block are connected to the block selection transistor.

19. The device according to claim 18, wherein
the plurality of blocks include a first block and a second block connected to the block selection transistor, and
the first block and the second block are alternately offset in a second plane that is orthogonal to the first plane.
